(19) United States
(12) Patent Application Publication
(10) Pub. No.: US 2024/0184950 A1
(43) Pub. Date: Jun. 6, 2024

(54) PRESS APPARATUS QUALITY DETERMINATION METHOD, PRESS APPARATUS QUALITY DETERMINATION SYSTEM, AND NON-TRANSITORY RECORDING MEDIUM

(71) Applicant: SUBARU CORPORATION, Tokyo (JP)

(72) Inventors: Yasunori SHIBATA, Tokyo (JP); Tetsuta SAKAKURA, Tokyo (JP)

(73) Assignee: SUBARU CORPORATION, Tokyo (JP)

(21) Appl. No.: 18/518,665

(22) Filed: Nov. 24, 2023

(30) Foreign Application Priority Data
Dec. 2, 2022 (JP) 2022-193580
Jul. 27, 2023 (JP) 2023-122751

(51) Int. Cl. G06F 30/20

(52) U.S. Cl. CPC G06F 30/20

(57) ABSTRACT

A press apparatus quality determination method is to be performed with use of a simulation of falling of a scrap. The simulation includes creating a three-dimensional model of a press die of a press apparatus, the scrap generated from a workpiece being processed by the press die, and a scrap chute guiding the scrap to an outside of the press apparatus, and simulating a movement of the scrap to be fallen on the scrap chute and to be discharged to the outside. The press apparatus quality determination method includes causing a force of gravity and a force that has a random magnitude within a range of a predetermined magnitude to act on the scrap generated in an initial stage of falling of the scrap on the scrap chute, and calculating a change amount of a fall attitude of the scrap from a start to an end of the falling.

### CROSS-REFERENCE TO RELATED APPLICATIONS

The present application claims priority from Japanese Patent Application No. 2022-193580 filed on Dec. 2, 2022 and Japanese Patent Application No. 2023-122751 filed on Jul. 27, 2023, the entire contents of each of which are hereby incorporated by reference.

### BACKGROUND

The disclosure relates to a press apparatus quality determination method, a press apparatus quality determination system, and a non-transitory recording medium, with use of a simulation of falling of a scrap in a press apparatus.

In a process of manufacturing a pressed product, after a workpiece which is a plate material is drawn by a press apparatus, trimming is performed in which a scrap part of the workpiece is cut and discarded.

In the trimming, the scrap cut from the workpiece falls on a scrap chute provided to the press apparatus. At this time, if the scrap remains inside the press apparatus due to an unexpected movement, this can be a cause of a defective product in the subsequent processing of the pressed product and a cause of damage to a press die.

In order to solve such an issue, in designing the press apparatus, a technique of simulating a fall movement of the scrap on the scrap chute has been developed.

For example, Japanese Unexamined Patent Application Publication No. 2022-146544 discloses a simulation method performed by a computer, the simulation method including: virtually creating a press apparatus and a scrap, the scrap being generated from a workpiece subjected to presswork by the press apparatus; and virtually reproducing a movement of the scrap to be fallen on a scrap chute and to be discharged to an outside.

### SUMMARY

An aspect of the disclosure provides a press apparatus quality determination method to be performed with use of a simulation of falling of a scrap. The simulation includes creating a three-dimensional model of a press die of a press apparatus, the scrap generated from a workpiece that is processed by the press die, and a scrap chute that guides the scrap to an outside of the press apparatus, and simulating a movement of the scrap to be fallen on the scrap chute and to be discharged to the outside. The press apparatus quality determination method includes causing a force of gravity and a force that has a random magnitude within a range of a predetermined magnitude to act on the scrap generated from the workpiece in an initial stage of falling of the scrap on the scrap chute, and calculating, based on the causing the force of gravity and the force having the random magnitude to act on the scrap, a change amount of a fall attitude of the scrap from a start of the falling to an end of the falling.

An aspect of the disclosure provides a press apparatus quality determination system including an arithmetic processor. The arithmetic processor is configured to create a three-dimensional model of a press die of a press apparatus, a scrap generated from a workpiece that is processed by the press die, and a scrap chute that guides the scrap to an outside of the press apparatus, and simulate a movement of the scrap to be fallen on the scrap chute and to be discharged to the outside. The arithmetic processor includes a force applier and an attitude-change-amount calculator. The force applier is configured to cause a force of gravity and a force that has a random magnitude within a range of a predetermined magnitude to act on the scrap generated from the workpiece in an initial stage of falling of the scrap on the scrap chute. The attitude-change-amount calculator is configured to calculate a change amount of a fall attitude of the scrap from a start of the falling to an end of the falling.

An aspect of the disclosure provides a non-transitory computer readable recording medium containing a press apparatus quality determination program. The press apparatus quality determination program causes, when executed by a computer, the computer to perform a method to be performed with use of a simulation of falling of a scrap. The simulation includes creating a three-dimensional model of a press die of a press apparatus, the scrap generated from a workpiece that is processed by the press die, and a scrap chute that guides the scrap to an outside of the press apparatus, and simulating a movement of the scrap to be fallen on the scrap chute and to be discharged to the outside. The method includes causing a force of gravity and a force that has a random magnitude within a range of a predetermined magnitude to act on the scrap generated from the workpiece in an initial stage of falling of the scrap on the scrap chute, and calculating, based on the causing the force of gravity and the force having the random magnitude to act on the scrap, a change amount of a fall attitude of the scrap from a start of the falling to an end of the falling.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the disclosure.

FIG. 1 is a block diagram illustrating a press apparatus quality determination system according to one example embodiment of the disclosure.

FIG. 2 is a schematic view of a press apparatus.

FIG. 3 is a cross-sectional view taken along a line A-A in FIG. 2.

FIG. 4 is a flowchart of a procedure of a method of simulating falling of a scrap.

FIG. 5 is a diagram for explaining a random force to be acted on the scrap.

FIG. 6A is a flowchart of a procedure of a press apparatus quality determination method.

FIG. 6B is a flowchart of a procedure of the press apparatus quality determination method.

FIG. 7A is a diagram for explaining an orientation of the scrap in an initial stage.

FIG. 7B is a diagram for explaining an orientation of the scrap after a force of gravity and a random force are acted on the scrap in the initial stage.

FIG. 7C is a diagram for explaining an orientation of the scrap in a scene following FIG. 7B.

FIG. 7D is a diagram for explaining an orientation of the scrap in a scene following FIG. 7C.

FIG. 8 is a perspective view of an example of a press die.

FIG. 9A is a diagram for explaining a fall movement a scrap.

FIG. 9B is a diagram for explaining the fall movement of the scrap.

FIG. 9C is a diagram for explaining the fall movement of the scrap.

FIG. 9D is a diagram for explaining the fall movement of the scrap.

FIG. 9E is a diagram for explaining the fall movement of the scrap.

FIG. 9F is a diagram for explaining the fall movement of the scrap.

FIG. 10A is a diagram for explaining an example of the fall movement of the scrap in a simulation when a movement of an upper die is not taken into account.

FIG. 10B is a diagram for explaining an example of the fall movement of the scrap in the simulation when the movement of the upper die is not taken into account.

FIG. 10C is a diagram for explaining an example of the fall movement of the scrap in the simulation when the movement of the upper die is not taken into account.

FIG. 10D is a diagram for explaining an example of the fall movement of the scrap in the simulation when the movement of the upper die is not taken into account.

FIG. 11A is a flowchart of a procedure of a press apparatus quality determination method.

FIG. 11B is a flowchart of a procedure of the press apparatus quality determination method.

### DETAILED DESCRIPTION

An existing simulation method includes repeating multiple times a simulation of a fall movement while changing a force applied to a scrap upon falling, calculating a probability that the scrap is discharged to an outside via a scrap chute, and performing a press apparatus quality determination based on the probability. In one example, when the probability that the scrap discharged to the outside of the press apparatus is high, a design quality of the press apparatus is determined to be satisfactory.

However, occurrence of a failure in falling of the scrap in the press apparatus even for once can lead to a breakage of a die. Accordingly, another evaluation criterion that makes it possible to avoid such a situation has been desired.

It is desirable to provide a press apparatus quality determination method, a press apparatus quality determination system, and a non-transitory recording medium that make it possible to improve accuracy of predicting a failure in falling of a scrap in determining a quality of a press apparatus, with use of a simulation of the falling of the scrap in the press apparatus.

### First Example Embodiment

In the following, some example embodiments of the disclosure are described in detail with reference to the accompanying drawings. Note that the following description is directed to illustrative examples of the disclosure and not to be construed as limiting to the disclosure. Factors including, without limitation, numerical values, shapes, materials, components, positions of the components, and how the components are coupled to each other are illustrative only and not to be construed as limiting to the disclosure. Further, elements in the following example embodiments which are not recited in a most-generic independent claim of the disclosure are optional and may be provided on an as-needed basis. The drawings are schematic and are not intended to be drawn to scale. Throughout the present specification and the drawings, elements having substantially the same function and configuration are denoted with the same reference numerals to avoid any redundant description. In addition, elements that are not directly related to any embodiment of the disclosure are unillustrated in the drawings.

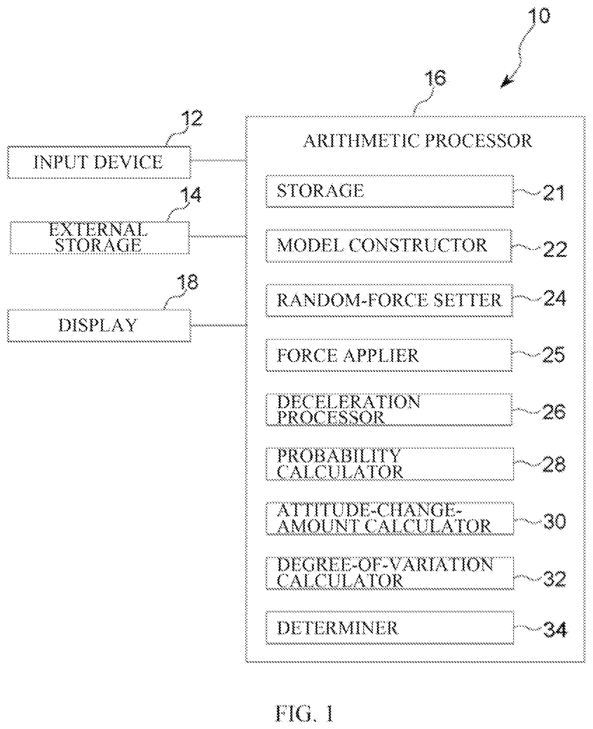

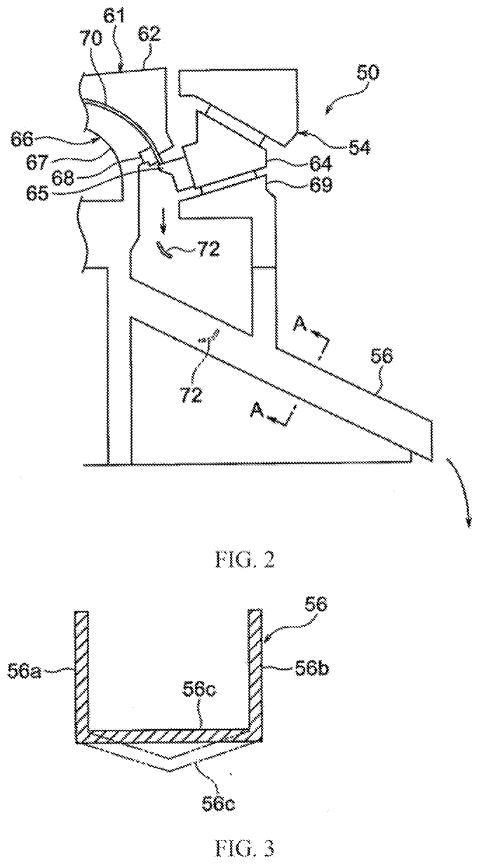

FIG. 1 is a block diagram illustrating a press apparatus quality determination system 10 according to an example embodiment. FIG. 2 is a schematic view of a press apparatus 50 that is to be created into a three-dimensional model by the quality determination system 10. FIG. 3 is a cross-sectional view of a scrap chute 56 taken along a line A-A in FIG. 2. The quality determination system 10 according to the example embodiment crates a three-dimensional model of a press die 54 of the press apparatus 50, a scrap 72 generated from a workpiece 70 that is processed by the press die 54, and a scrap chute 56 that guides the scrap 72 to an outside of the press apparatus 50, and simulates a movement of the scrap 72 to be fallen on the scrap chute 56 and to be discharged to the outside. The quality determination system 10 may perform quality determination of the press apparatus 50 based on a result of the simulation.

The press apparatus 50 on which the quality determination is to be performed may press the workpiece 70 that is a plate material, and execute trimming to cut a scrap part of the workpiece 70. As illustrated in FIG. 2, the press apparatus 50 may include the press die 54, and the scrap chute 56 that guides the scrap 72 cut from the workpiece 70 to the outside of the press apparatus 50.

The press die 54 may be a member that executes presswork and trimming on the workpiece 70, and include a lower die 66 fixed to an installation site and an upper die 61 movable upward and downward with respect to the lower die 66. The lower die 66 may include a lower cutting blade 68 supported on a lower die body 67. The upper die 61 may include a pad 62 that holds the workpiece 70 placed on the lower die 66, a cam slider 64, and an upper cutting blade 65. The cam slider 64 may move forward toward the workpiece 70 while being abutted against a cam driver 69 provided in the lower die body 67 with a downward movement of the upper die 61, and move backward with an upward movement of the upper die 61. The upper cutting blade 65 may be provided on the cam slider 64 in such a manner as to oppose the lower cutting blade 68.

The workpiece 70 may be cut by the upper cutting blade 65 and the lower cutting blade 68 of the press die 54, and a part of the cut workpiece 70 may fall as the scrap 72 on the scrap chute 56 of the press apparatus 50.

The scrap chute 56 may be disposed below the lower cutting blade 68 of the press die 54, and extend obliquely with respect to a vertical direction. In the illustrated example embodiment, the scrap chute 56 and the lower die body 67 may be provided integrally. As illustrated in FIG. 2, the scrap chute 56 may have a side wall 56a and a side wall 56b extending in the vertical direction, and a bottom wall 56c coupling respective lower end parts of the side walls 56a and 56b to each other, and an upper part of the scrap chute 56 may be open. An upper surface of the bottom wall 56c may be smooth. The scrap 72 may slide downward in a tilting direction along the upper surface of the bottom wall 56c and be discharged to the outside of the press apparatus 50.

The quality determination system 10 according to the example embodiment may simulate a way in which the scrap 72 falls and is discharged based on setting data of the press apparatus 50, and determine whether a design quality of the press apparatus 50 is satisfactory or unsatisfactory based on a change amount of a fall attitude of the scrap 72. Performing the quality determination with use of the simulation makes it possible to solve, in a stage of designing the press apparatus 50, a trouble that the scrap 72 remains inside the press apparatus 50. Hereinafter, components included in the quality determination system 10 according to the example embodiment will be described.

The quality determination system 10 may include a single computer such as a personal computer or multiple computers coupled to each other via a network. As illustrated in FIG. 1, the quality determination system 10 may include an input device 12 serving as an information input unit, an external storage 14 serving as a storage, an arithmetic processor 16 serving as an arithmetic unit and a processor, and a display 18 serving as an output unit.

Non-limiting examples of the input device 12 may include a keyboard, a mouse, and a touch panel. The external storage 14 may be an external memory coupled to the arithmetic processor 16, and may be any storage such as a hard disk drive (HDD) or a solid state drive (SSD).

The arithmetic processor 16 may be a computer including a microcomputer, and may include, for example, a central processing unit (CPU) serving as a data processing unit, an internal memory such as a RAM or a ROM, and an input/output interface adapted for communicating with other devices. The data processing unit of the arithmetic processor 16 may not be limited to the CPU, and may be, for example, a field programmable gate array (FPGA), an application specific integrated circuit (ASIC), an application specific standard product (ASSP), or a system on chip (SOC).

It may be possible for the arithmetic processor 16 to execute, in the CPU, a press apparatus quality determination program recorded in the internal memory, a press apparatus quality determination program recorded in a non-transitory tangible recording medium readable via the external storage 14, or a press apparatus quality determination program loaded from the outside via an unillustrated network or an unillustrated communication device. With use of the press apparatus quality determination program, the arithmetic processor 16 may: simulate the press apparatus 50 that is an analysis target designated by the input device 12 and the way in which the scrap 72 falls on the scrap chute 56 and is discharged outside; and calculate the change amount of the fall attitude of the scrap 72. The scrap 72 may be generated from the workpiece 70 by simulatively executing presswork and trimming on the workpiece 70.

The arithmetic processor 16 may include a storage 21 serving as the internal memory, a model constructor 22, a random-force setter 24, a force applier 25, a deceleration processor 26, a probability calculator 28, an attitude-change-amount calculator 30, a degree-of-variation calculator 32, and a determiner 34.

The model constructor 22 may read respective pieces of shape data of the press apparatus 50, the workpiece 70, and the scrap 72 to create a three-dimensional model of the press apparatus 50, the workpiece 70, and the scrap 72. The shape data may be entered into the arithmetic processor 16 via the input device 12 or the external storage 14. In the example embodiment, the three-dimensional model may be created with use of CAD data that is used in designing the press apparatus 50 and the workpiece 70.

The random-force setter 24 may set a force F having a random magnitude within a range of a predetermined magnitude. The force F may be caused to act on the scrap 72 in an initial stage of the falling of the scrap 72. The force F (hereinafter, also referred to as a “random force F”) having the random magnitude may be expressed by a random mathematical function represented by Expression (1) below.

Force=(upper limit, lower limit) Expression (1)

In the example embodiment, as indicated in Expressions (2), (3), and (4) below, the random force F may be set for each of an X direction, a Y direction, and a Z direction that are orthogonal to each other.

X direction force=(upper limit xᵤₚ, lower limit x_{low}) Expression (2)

Y direction force=(upper limit yᵤₚ, lower limit y_{low}) Expression (3)

Z direction force=(upper limit zᵤₚ, lower limit z_{low}) Expression (4)

In the example embodiment, for example, a positive direction of the Y direction may be set to a gravity direction and the lower limit ylow may be set to 0. The upper limit xᵤₚ, the upper limit yᵤₚ, and the upper limit zᵤₚ may each be set to a positive value, and the lower limit x_{low} and the lower limit z_{low} may each be set to a negative value. The random force F to be acted on the scrap 72 may be a resultant force of the X direction force, the Y direction force, and the Z direction force set in Expressions (2) to (4). The random force F may be set to have a magnitude range in such a manner that the magnitude of the random force F is smaller than the magnitude of the force of gravity acting on the scrap 72.

The force applier 25 causes the force of gravity and the random force F set by the random-force setter 24 to act on the scrap 72. The random force F is applied in the initial stage of the falling of the scrap 72 when the scrap 72 is generated from the workpiece 70.

The deceleration processor 26 may perform a deceleration process on the scrap 72 when a fall velocity v of the scrap 72 exceeds a predetermined threshold vₜₕ (hereinafter, also referred to as a “velocity threshold vₜₕ”). The deceleration process may be performed in accordance with a predetermined rule. In the example embodiment, when the velocity v exceeds the velocity threshold vₜₕ, the deceleration processor 26 may perform a process of halving a magnitude of the fall velocity v of the scrap 72 as indicated by Expression (5) below.

v=v/2 Expression (5)

The probability calculator 28 may calculate a probability that the scrap 72 is discharged appropriately to the outside of the press apparatus 50 in the simulation based on a result of the simulation of the falling of the scrap.

The attitude-change-amount calculator 30 calculates the change amount of the fall attitude of the scrap 72 from a start of the falling to an end of the falling of the scrap 72. In one example, the change amount of the fall attitude of the scrap 72 may be determined by setting a vector V having a predetermined magnitude extending from a predetermined point in the scrap 72 in a predetermined direction, and using an inner product of the vector V. In the example embodiment, the vector V used in determining an attitude change amount may be a unit vector extending from the center of gravity of the scrap 72 in the normal direction, in other words, the unit normal vector V of the center of gravity.

The change amount U of the fall attitude of the scrap 72 may be determined by Expression (6) below using the inner product of the unit normal vector V.

$$\\ \begin{matrix}Change amount U = {\sum }_{m = 1}^{M} ( 1 - ( V 2 \cdot V 1 ) ) & Expression ( 6 )\end{matrix}$$

Here, V1 represents a unit normal vector indicating an orientation of the scrap 72 at a certain point in time, and V2 represents a unit normal vector indicating an orientation of the scrap 72 after a predetermined period has elapsed from the certain point in time. “M” represents the number of frames in a scene obtained by dividing in equal parts a fall time Te in which the scrap 72 falls, and “m” represents a number indicating each scene.

The attitude-change-amount calculator 30 may further calculate a “fall-attitude average change amount AveU” when a fall movement is repeated multiple times in the simulation. When the number of times of the fall movement is n times, the fall-attitude average change amount AveU(n) may be determined using Expression (7) below.

Fall-attitude average change amount AveU(n)=(AveU(n−1)×(n−en)+U/(n−en+1) Expression (7)

Here, “n” represents the number of times of the fall movement, “en” represents the number of times the scrap 72 is jammed in the press apparatus 50, and “U” represents the change amount calculated by Expression (6).

The degree-of-variation calculator 30 may calculate, when the fall movement of the scrap 72 is repeated a predetermined number of times in the simulation, a degree of variation of the change amount of the fall attitude of the scrap 72 based on the attitude change amount calculated by the attitude-change-amount calculator 30. In the example embodiment, a variance σ² is determined as the degree of variation. The variance σ² may be determined using Expression (8) below.

Variance σ²=Σ(U−AveU(n))²/N Expression (8)

Here, “U” represents the change amount calculated by Expression (6), and AveU(n) is the fall-attitude average change amount calculated by Expression (7).

The determiner 34 may determine whether the design quality of the press apparatus 50 is satisfactory or unsatisfactory based on the degree of variation calculated by degree-of-variation calculator 32. In one example, the determiner 34 may determines that, if the degree of variation (i.e., the variance σ²) calculated by the degree-of-variation calculator 32 is less than or equal to a predetermined threshold, the design quality of the press apparatus 50 is satisfactory, and if the degree of variation exceed the predetermined threshold, the design quality is low. The determiner 34 according to the example embodiment may determine whether the design quality of the press apparatus 50 is satisfactory or unsatisfactory further based on the probability calculated by the probability calculator 28.

A result of the simulation of the falling of the scrap and a result of the determination analyzed by the arithmetic processor 16 may be displayed on the display 18. The display 18 may be a device that makes it possible to visually display information. Non-limiting examples of the display 18 may include a liquid crystal display, an organic EL display, a plasma display, and a cathode ray tube display. The arithmetic processor 16 may cause the display 18 to display not only the result of the simulation but also a process of the simulation.

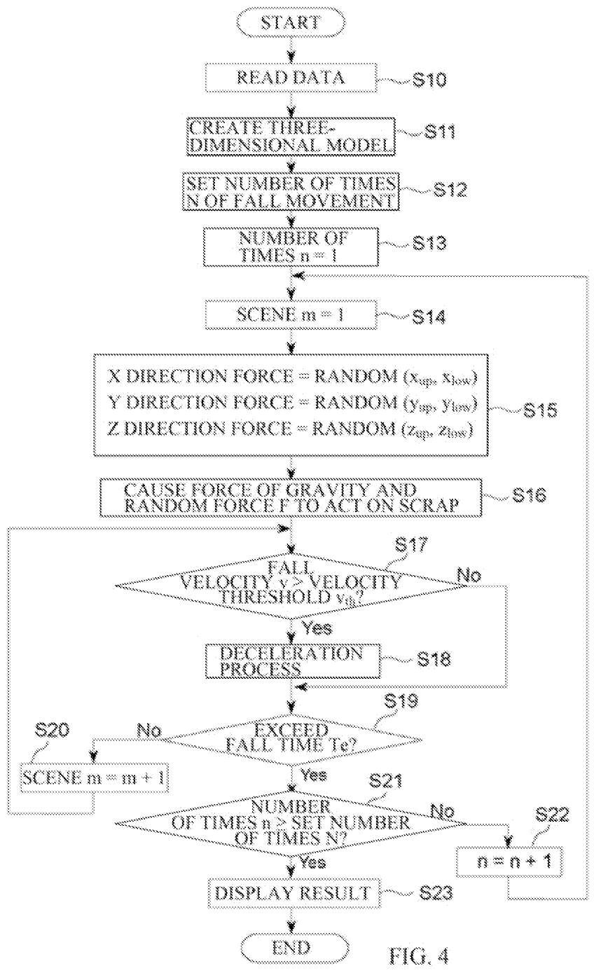

Described next is, with reference to FIG. 4, a procedure of the simulation of the falling of the scrap performed by the quality determination system 10.

As illustrated FIG. 4, in step S10, the quality determination system 10 may read various pieces of shape data and calculation condition data from the external storage 14, the internal memory of the arithmetic processor 16, or both. The shape data may include respective pieces of shape data of the press apparatus 50, the workpiece 70 and the scrap 72, and may also include shape-changed data of the workpiece 70 after being processed. The calculation condition data may include, for example, movable cycle time (e.g., 6 seconds) of the upper die 61 of the press die 54, pressure applied by the press die 54, the fall time Te in which the scrap 72 falls (e.g., 4 seconds), the number of frames M (“M” is an integer of 2 or more) in a scene obtained by dividing in equal parts the fall time Te, the upper limit and the lower limit of the random mathematical function described above, the magnitude of the force of gravity, and a condition of a reaction force that the scrap 72 receives from the scrap chute 56 when the scrap 72 is abutted against the scrap chute 56. In step S11, the model constructor 22 may create the three-dimensional model of the press apparatus 50, the workpiece 70, and the scrap 72 based on the pieces of read shape data.

In step S12, the quality determination system 10 may set the number of times N (“N” is an integer of 2 or more) the fall movement of the scrap 72 is to be performed. The input device 12 may set the number of times N. In step S13, the quality determination system 10 may reset the number of times n the fall movement of the scrap 72 is performed, and may set the number of times n to 1.

In step S14, the quality determination system 10 may set a scene m to 1 for the fall movement of the scrap 72. Here, “m” represents a number that indicates each scene of the number of frames M read as calculation condition data, and is an integer of 1 to M. In the example embodiment, the scene 1 may be set to a situation in which the scrap 72 is generated due to cutting of the workpiece 70, in other words, a situation in the initial stage of the falling of the scrap 72.

In step S15, the random-force setter 24 may set the random force F based on the random mathematical function of each of Expressions (2) to (4) described above. In step S16, the quality determination system 10 may cause the force of gravity and the random force F to act on the scrap 72 of the scene 1. Those forces may initiate the fall movement of the scrap 72.

In step S17, the quality determination system 10 may determine whether the fall velocity v of the scrap 72 exceeds a predetermined velocity threshold vₜₕ. If the quality determination system 10 determines that the fall velocity v exceeds the velocity threshold Vth (step S17: Yes), the deceleration processor 26 may execute a deceleration process on the fall velocity v in step S18.

Here, the deceleration process of step S18 will be described. To reduce an amount of calculation for the simulation, a length of an interval of time of calculating the fall velocity of the scrap 72 may be increased (i.e., a value of the number of frames M may be decreased). This can cause, however, a phenomenon that the scrap 72 digs into the scrap chute 56 in the scene m during the simulation. Such a digging phenomenon may be a phenomenon that does not occur in the actual press apparatus 50. In the simulation, calculating the reaction force that the scrap 72 receives from the scrap chute 56 based on such a digging state can increase the reaction force excessively and can cause a phenomenon that scrap 72 bounces back from the scrap chute 56 (hereinafter, also referred to as a “bounce-back phenomenon”). To eliminate the occurrence of the bounce-back phenomenon, decreasing the interval of time of calculating the fall velocity of the scrap 72 (i.e., increasing the value of the number of frames M) may be effective. However, increasing the number of frames M can cause the amount of calculation to be enormous. The fall velocity v of the scrap 72 becomes the maximum immediately before the scrap 72 abuts against the scrap chute 56. Accordingly, in the example embodiment, the quality determination system 10 may set a threshold to the fall velocity v, and, if the fall velocity v exceeds the velocity threshold vₜₕ (step S17: Yes), the quality determination system 10 may perform the deceleration process. The quality determination system 10 may thus suppress the increase in the amount of calculation by increasing the interval of time of calculating the fall velocity v of the scrap 72 while preventing the occurrence of the bounce-back phenomenon described above (step S18).

After the deceleration process is performed, the quality determination system 10 may determine in step S19 whether a fall time of the scrap 72 exceeds a set fall time Te of the scrap 72. The fall time Te is set to a time until the scrap 72 is discharged to the outside via the scrap chute 56 without remaining inside the press apparatus 50. In step S17, if the fall velocity v is less than or equal to the velocity threshold vₜₕ (step S17: No), the process may proceed to step S19 without the quality determination system 10 performing the deceleration process.

If the quality determination system 10 determines in step S19 that the fall time of the scrap 72 does not exceed the fall time Te (step S19: No), the quality determination system 10 may increment the scene m in step S20, and the process may continue from step S17 again. If the quality determination system 10 determines in step S19 that the fall time of the scrap 72 exceeds the fall time Te (step S19: Yes), the quality determination system 10 may determine in step S21 whether the number of times n of the fall movement of the scrap 72 is greater than or equal to the set number of times N. If the quality determination system 10 determines that the number of times n is less than the set number of times N (step S21: No), the quality determination system 10 may increment the number of times n in step S22, and the process may continue from step S14 again (i.e., the process of newly causing the scrap 72 to fall from an initial stage position of the falling of the scene 1 may continue).

FIG. 5 is a diagram for explaining the random force F to be acted on the scrap 72. In the fall movement when the number of times n is 1, a random force F1 may be applied in the initial stage of the falling of the scrap 72 with use of the random mathematical function. In the fall movement when the number of times n is 2, a random force F2 may be applied in the initial stage of the falling of the scrap 72. As described above, with use of the random mathematical function, the random force F to be acted on the scrap 72 may change each time the number of times n changes. Note that the force of gravity to be acted on the scrap 72 in the initial stage of the falling may be constant.

If the quality determination system 10 determines in step S21 that the number of times n is greater than or equal to the set number of times N (step S21: Yes), the process may proceed to step S23, and the quality determination system 10 may display a result of the simulation (e.g., whether the scrap 72 is jammed, or a trajectory of the falling of the scrap 72) on, for example, a display of the display 18. In the example embodiment, the quality determination system 10 may display, on the display 18, the probability calculated by the probability calculator 28, in other words, the probability that the scrap 72 is appropriately discharged to the outside of the press apparatus 50 in the fall movement performed N times. In the example embodiment, when the scrap 72 is jammed, the quality determination system 10 may cause the display to display a state in which the scrap 72 is jammed inside the press apparatus 50. In the example illustrated in FIG. 5, the scrap 72 jammed in the scrap chute 56 is indicated by a virtual line, and this makes it possible to visually recognize a location where the jam has occurred.

In the simulation of the fall movement of the scrap 72 described above, it is possible to change the fall movement of the scrap 72 each time when the scrap 72 virtually falls on the scrap chute 56 by causing the force F having the random magnitude within the range of the predetermined magnitude to act on the scrap 72. This makes it possible for the actually manufactured press apparatus 50 to reproduce, in the simulation, the fall movement of the scrap 72 that changes each time die to a force other than the force of gravity to be acted on the scrap 72 when the scrap 72 is generated. Non-limiting examples of the force other than the force of gravity may include a pressing force of the upper die 61 of the press die 54 at the time of cutting, a restoring force generated by elastic deformation of the workpiece 70 and the scrap 72, a moment of inertia of the scrap 72 itself, an air resistance force, and a force caused by a shear angle between the upper cutting blade 65 and the lower cutting blade 68.

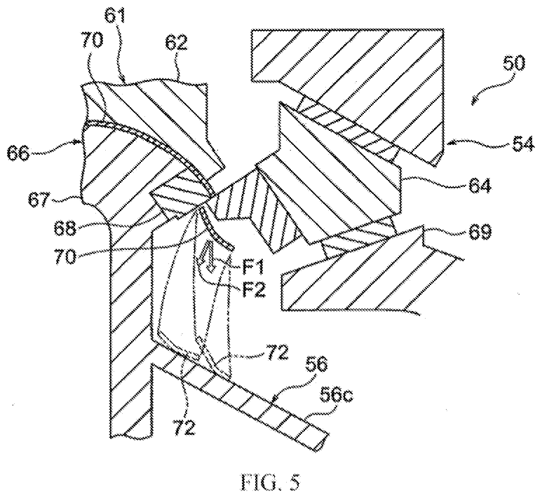

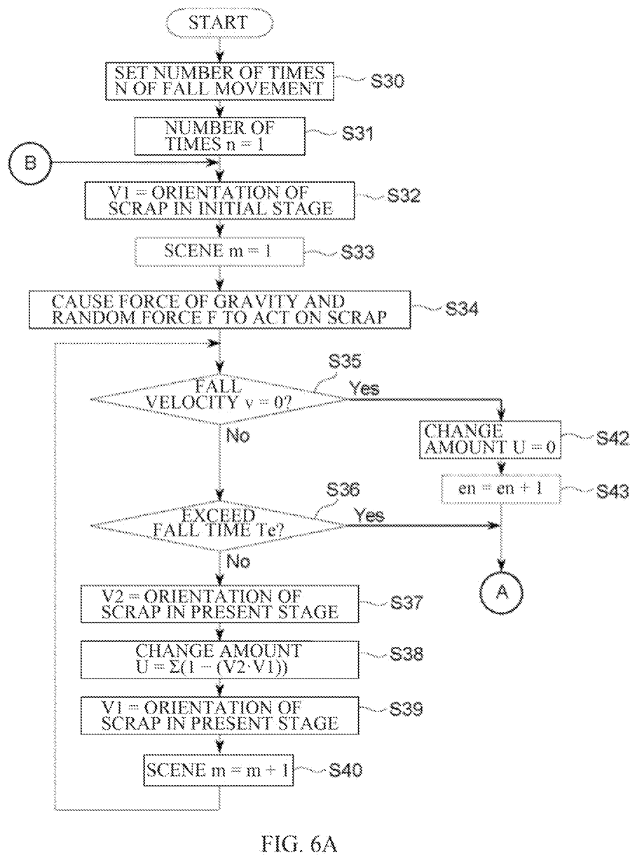

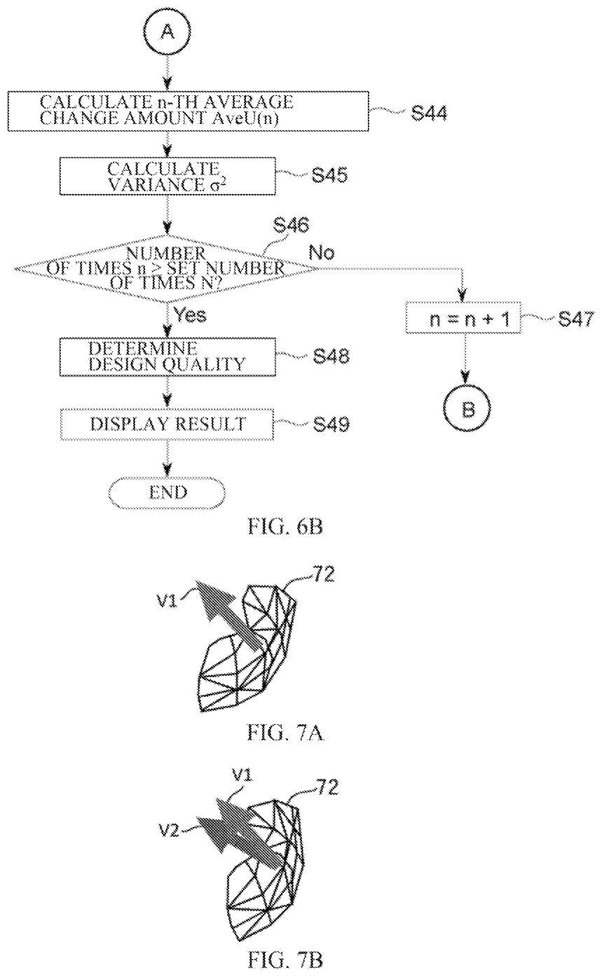

Described next is, with reference to flowcharts of FIGS. 6A and 6B, a procedure of a quality determination method of determining a quality of the press apparatus 50 to be executed by the arithmetic processor 16 of the quality determination system 10.

As illustrated in FIG. 6A, in step S30, the arithmetic processor 16 may set the number of times N (“N” is an integer of 2 or more) the fall movement of the scrap 72 is to be performed. In step S31, the arithmetic processor 16 may reset the number of times n the fall movement of the scrap 72 is performed, and may set the number of times n to 1.

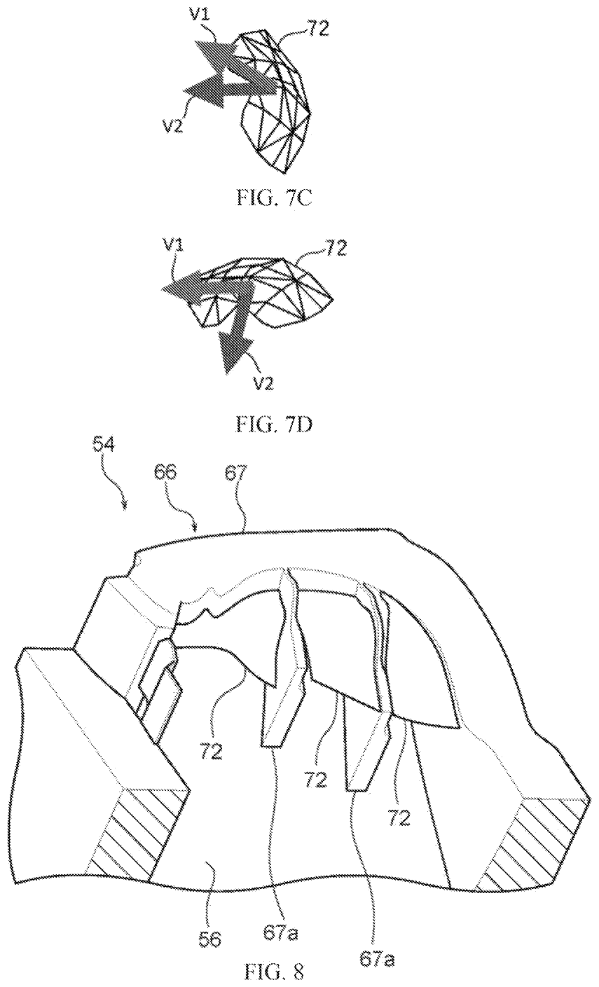

In step S32, the arithmetic processor 16 may set the orientation of the scrap 72 in the initial stage as the vector V1 using the unit normal vector V of the center of gravity of the scrap 72. FIG. 7A is a diagram for explaining the orientation of the scrap 72 in the initial stage, and illustrates the unit normal vector V1 of the scrap 72. Note that the scrap 72 is illustrated in a three-dimensional mesh model.

In step S33, the arithmetic processor 16 may set the scene m to 1 for the fall movement of the scrap 72. Here, “m” represents the number that indicates each scene of the number of frames M read as the calculation condition data, and is an integer of 1 to M. The scene 1 may be set to the situation in which the scrap 72 is generated due to cutting of the workpiece 70, in other words, the situation in the initial stage of the falling of the scrap 72.

In step S34, the random-force setter 24 may set the random force F based on the random mathematical function of each of Expressions (2) to (4) described above, and cause the force of gravity and the random force F to act on the scrap 72. Those forces may initiate the fall movement of the scrap 72.

In step S35, the arithmetic processor 16 may determine whether the fall velocity v of the scrap 72 is zero, in other words, whether the scrap 72 stops and is jammed. If the arithmetic processor 16 determines that the fall velocity v is not zero, in other words, that the scrap 72 is falling without being jammed (step S35: No), the process may proceed to step S36, and the arithmetic processor 16 may determine whether the fall time of the scrap 72 exceeds the set fall time Te. As described above, the fall time Te is set to the time until the scrap 72 is discharged to the outside via the scrap chute 56 without remaining inside the press apparatus 50.

If the arithmetic processor 16 determines in step S36 that the fall time of the scrap 72 does not exceed the fall time Te (step S36: No), the arithmetic processor 16 may set in step S37 the orientation of the scrap 72 in a present stage as a vector V2 using the unit normal vector V of the center of gravity of the scrap 72. FIG. 7B is a diagram for explaining an orientation of the scrap 72 after the force of gravity and the random force are acted on the scrap 72 in the initial stage. FIG. 7B illustrates a state of the scrap 72 after the forces have been applied, the vector V2 indicating the orientation at this time, and the vector V1 in the initial stage illustrated in FIG. 7A.

In step S38, the attitude-change-amount calculator 30 calculates the change amount U of the fall attitude based on Expression (6) described above, with use of the inner product between the vector V1 indicating the orientation of the scrap 72 in the previous stage and the vector V2 indicating the orientation in the present stage. In one embodiment, the calculating the change amount U of the fall attitude may serve as “calculating a change amount”. If the arithmetic processor 16 sets the scene m to 1, the arithmetic processor 16 may calculate the change amount U based on the inner product between the vector V1 and the vector V2 illustrated in FIG. 7B.

In step S39, the arithmetic processor 16 may set the orientation of the scrap 72 in the present stage as the vector V1. In step S39 where the scene m is set to 1, the arithmetic processor 16 may newly set the vector V2 illustrated in the FIG. 7B as the vector V1 (see the vector V1 in FIG. 7C).

In step S40, the arithmetic processor 16 may increment the scene m, and the process may continue from step S35 again. For example, if the arithmetic processor 16 increments the scene m that has been set to 1 and thus causes the scene m to become 2, and the process proceeds to step S37 through step S35 and step S36 again, the orientation of the scrap 72 in the present stage in step S37 may be the vector V2 of the scrap 72 illustrated in FIG. 7C. Further, if the process proceeds to step S40 through step S38 and step S39 and the arithmetic processor 16 increments the scene m and thus causes the scene m to become 3, and the process proceeds to step S36 and thereafter to step S37 from step S35 again, the orientation of the scrap 72 in the present stage in step S37 may be the vector V2 of the scrap 72 illustrated in FIG. 7D.

If the arithmetic processor 16 determines in step S35 that the fall velocity v is zero, in other words, that the scrap 72 stops and is jammed in the press apparatus 50 (step S35: Yes), the arithmetic processor 16 may set in step S42 the change amount U of the fall attitude of the scrap 72 to zero (change amount U=0). In step S43, the arithmetic processor 16 may increment the number of times en the scrap 72 has jammed (the number of times en the jam has occurred=en+1), and the process may proceed to step S44 illustrated in FIG. 6B. If the arithmetic processor 16 determines in step S35 that the fall velocity v is not zero (step S35: No), and determines in step S36 that the fall time of the scrap 72 exceeds the fall time Te (step S36: Yes), the process may proceed to step S44 illustrated in FIG. 6B.

In step S44, the attitude-change-amount calculator 30 may calculate the fall-attitude average change amount AveU of the scrap 72 using Expression (7) described above. In step S45, the degree-of-variation calculator 32 may calculate the variance σ² that is the degree of variation of the change amount of the fall attitude of the scrap 72.

In step S46, the arithmetic processor 16 may determine whether the number of times n of the fall movement of the scrap 72 is greater than or equal to the set number of times N. If the arithmetic processor 16 determines that the number of times n is less than the set number of times N (step S46: No), the arithmetic processor 16 may increment the number of times n in step S47, and the process may continue from step S32 illustrated in FIG. 6A again (i.e., the process of newly setting the orientation of the scrap 72 to the orientation of the scrap 72 in the initial stage, and causing the scrap 72 to fall from the initial stage position of the falling of the scene 1 may continue).

If the arithmetic processor 16 determines in step S46 that the number of times n is greater than or equal to the set number of times N (step S46: Yes), the process may proceed to step S48, and the determiner 34 may determine whether the design quality of the press apparatus 50 is satisfactory or unsatisfactory based on a value of the calculated variance σ². The determiner 34 may determine that, if the value of the variance calculated in step S45 is less than or equal to the predetermined threshold, the design quality is satisfactory, and if the value of the variance exceeds the predetermined threshold, the design quality is low.

In the example embodiment, the determiner 34 may further perform the determination based on the probability (the probability that the scrap 72 is discharged) calculated by the probability calculator 28. It is possible to calculate the probability based on the number of times N of the fall movement and the number of times en that the scrap 72 is jammed and remains inside the press apparatus 50. For example, when the number of times N is 200, and, out of such number of times N, the number of times en the jam has occurred is 10, a probability R may be determined as follows: probability R=(200−10)/200×100=95(%). The determiner 34 may determine that the design quality is satisfactory if the calculated probability is greater than or equal to a predetermined probability threshold and the value of the variance is less than or equal to the predetermined threshold. The determiner 34 may determine that the design quality is low if the probability calculated by the probability calculator 28 is less than the predetermined probability threshold and/or the value of the variance exceeds the predetermined threshold. In step S49, a result of the determination is displayed on, for example, the display of the display 18.

As described above, in the quality determination system 10 configured to determine the quality of the press apparatus 50 and the quality determination method of determining the quality of the press apparatus 50 according to the example embodiment, it is possible to determine that the trouble that the scrap 72 remains inside the press apparatus 50 is prevented from occurring easily and the design quality is satisfactory, if the degree of variation of the fall attitude of the scrap 72 is as small as less than or equal to the predetermined threshold and the fall attitude of the scrap 72 is stable. In contrast, if the degree of variation of the change amount of the fall attitude of the scrap 72 exceeds the predetermined threshold and the fall attitude of the scrap 72 is unstable, it is highly possible that the scrap 72 remains inside the press apparatus 50 in an unexpected attitude even if the probability that the scrap 72 is discharged to the outside of the press apparatus 50 is high, and it is thus possible to determine that the design quality is low. As described above, the quality determination method according to the example embodiment includes determining the change amount of the fall attitude of the scrap 72, and focusing on the degree of variation of the change amount. This makes it possible improve accuracy of predicting the failure in the falling.

If the quality determination system 10 determines that the design quality is low, for example, it may be possible to change a design in such a manner that the scrap 72 falls easily by changing a shape of a bottom surface of the scrap chute 56 to have a V shape as illustrated in FIG. 3. Further, for example, it may also be possible to control the fall attitude of the scrap 72 by providing, between a position of the start of the falling of the scrap 72 and the scrap chute 56, a rod-shaped member configured to change the fall attitude of the scrap 72, and causing the scrap 72 to hit the rod-shaped member.

In some embodiments, the vector V extending from the center of gravity of the scrap 72 is used as the change amount of the orientation of the scrap 72, and the change in the orientation of the vector V is determined using the inner product. This makes it possible to determine the change amount by simple calculation.

### Second Example Embodiment

Described next is the quality determination system 10 according to a second example embodiment. A hardware configuration of a computer in the quality determination system 10 according to the second example embodiment is similar to that of the first example embodiment illustrated in FIG. 1, and thus detailed explanation thereof is omitted here. In a simulation performed by the quality determination system 10 according to the second example embodiment, a movement of the upper die 61 of the press die 54 may be taken into account.

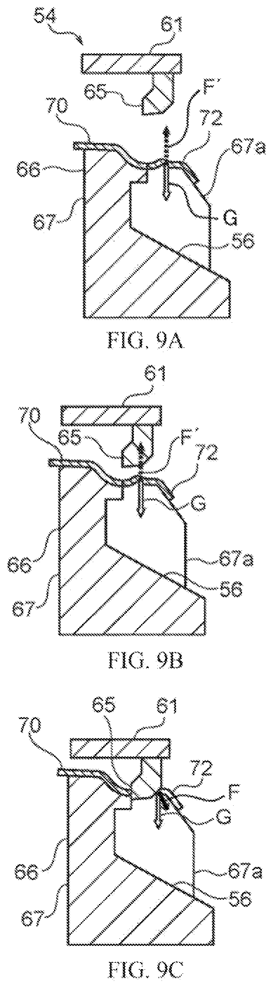

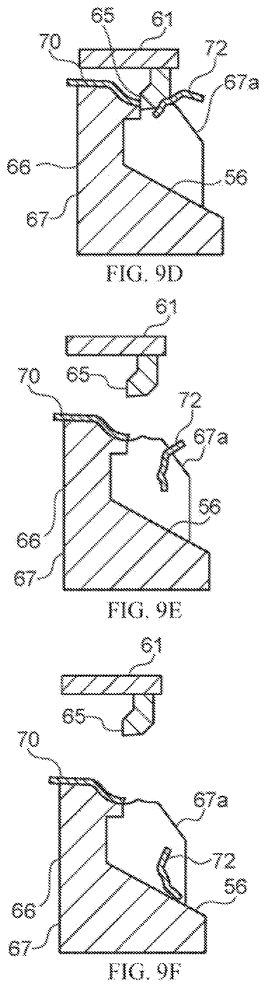

FIG. 8 is a perspective view of an example of the press die 54, and FIGS. 9A to 9F each illustrates a state in which the scrap 72 illustrated in FIG. 8 is separated from the workpiece 70. FIG. 8 illustrates a part of the lower die 66 of the press die 54 and the scrap chute 56 provided integrally with the lower die 66, and in addition, a state in which the scrap 72 is divided into three pieces by the upper cutting blade 65 of the upper die 61, and the three pieces fall on the scrap chute 56. For example, when a scrap part separated from the workpiece 70 is large, the scrap part may be divided into multiple pieces and removed, as illustrated in FIG. 8. The scrap part may be supported from below by a support 67a erected on the lower die body 67 during a period until the scrap part is cut from the workpiece 70 by the upper cutting blade 65. In FIG. 8, as an example, two supports 67a protruding from the bottom surface of the scrap chute 56 are illustrated.

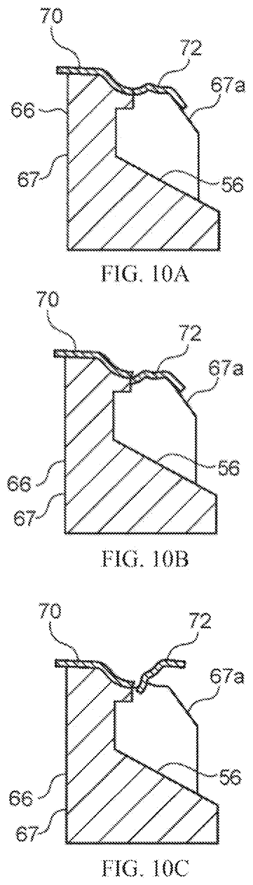

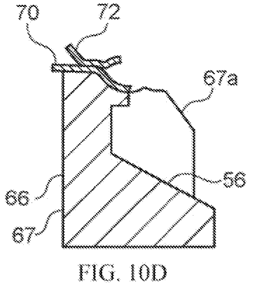

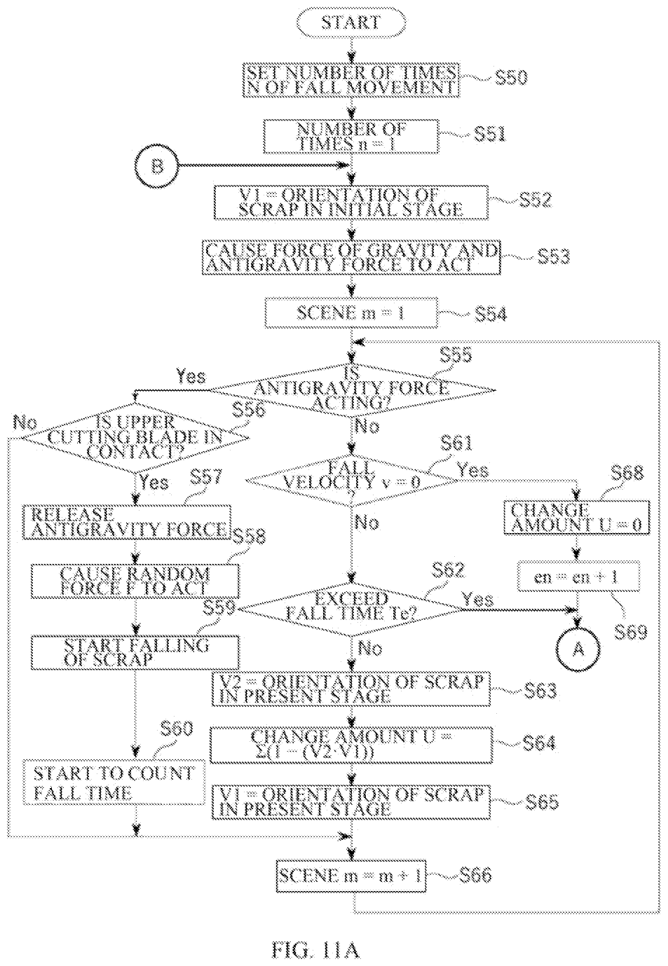

As illustrated in FIGS. 9C and 9D, the scrap 72 may sometimes undergo a movement of hitting the support 67a and bouncing upward upon falling. As illustrated in FIGS. 9E and 9F, the scrap 72 that has bounced upward may hit the upper die 61 and return to the scrap chute 56. If the movement of the upper die 61 is not taken into account in the simulation of the fall movement of the scrap 72, a movement can occur in which, as illustrated in FIGS. 10A to 10D, the scrap 72 rides on the lower die 66 after hitting the support 67a and being bounced back. In the simulation performed by the quality determination system 10 of the example embodiment, the movement of the upper die 61 is taken into account as illustrated in FIGS. 9A to 9F. The quality determination system 10 according to the second example embodiment further includes configurations described below in addition to the configurations of the first example embodiment described above.

In the quality determination system 10 according to the second example embodiment, the arithmetic processor 16 may store data that the press die 54 includes the lower die 66 and the upper die 61, and movement data that the downward movement of the upper die 61 with respect to the lower die 66 generates the scrap 72. In one example, data of movement that the upper die 61 moves upward and downward with respect to the fixedly disposed lower die 66 may be stored. Those pieces of data may be read from the external storage 14 into the arithmetic processor 16 together with other pieces of data, or may be loaded from the outside via an unillustrated network or an unillustrated communication device into the storage 21 of the arithmetic processor 16. The model constructor 22 of the arithmetic processor 16 may construct a three-dimensional model of the lower die 66 and the upper die 61 of the press die 54. The simulation may reproduce the movement in which the upper die 61 moves upward and downward with respect to the lower die 66.

As illustrated in FIG. 9A, the force applier 25 of the arithmetic processor 16 may cause the force of gravity G and a force F′ that is in a direction opposite to the gravity direction and has a magnitude that is equal to a magnitude of the force of gravity G to act on the scrap 72, during a period from when the upper die 61 moves downward to when the scrap 72 is generated from the workpiece 70. Hereinafter, the force F′ in the direction opposite to the gravity direction is also referred to as an “antigravity force F”. The force applier 25 may cause the random force F set by the random-force setter 24 to act on the scrap 72 in the initial stage of the falling of the scrap 72 in which the scrap 72 is generated.

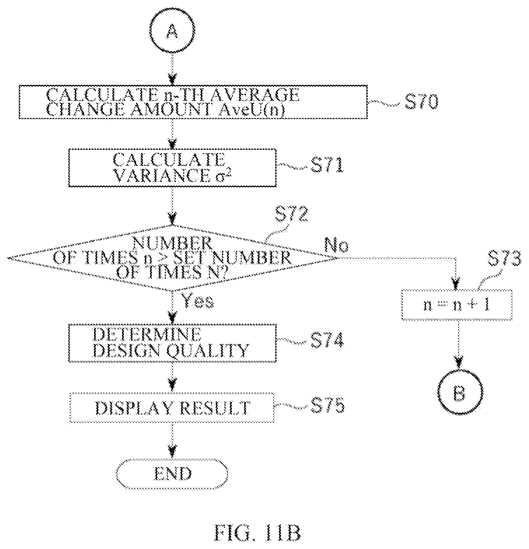

Described next is, with reference to flowcharts of FIGS. 11A and 11B, a procedure of a quality determination method of determining a quality of the press apparatus 50 to be executed by the arithmetic processor 16 of the quality determination system 10. An example embodiment of the disclosure is not configured by the steps described in a flowchart, but may include each of the steps described in the flowchart. The simulation performed by the quality determination system 10 may include the data that the press die 54 includes the lower die 66 and the upper die 61, and the movement data that the downward movement of the upper die 61 with respect to the lower die 66 generates the scrap 72.

As illustrated in FIG. 11A, in step S50, the arithmetic processor 16 may set the number of times N (“N” is an integer of 2 or more) the fall movement of the scrap 72 is to be performed. In step S51, the arithmetic processor 16 may reset the number of times n the fall movement of the scrap 72 is performed, and may set the number of times n to 1.

In step S52, the arithmetic processor 16 may set the orientation of the scrap 72 in the initial stage as the vector V1 using the unit normal vector V of the center of gravity of the scrap 72. In step S53, the arithmetic processor 16 may cause the force of gravity and the antigravity force to act on the scrap 72 to maintain the rest state of the scrap 72. In FIG. 9A, the force of gravity G and the antigravity force F′ acted on the scrap 72 are each indicated by an arrow.

In step S54, the arithmetic processor 16 may set the scene m to 1 for the fall movement of the scrap 72. Here, “m” represents the number that indicates each scene of the number of frames M read as the calculation condition data, and is an integer of 1 to M. As illustrated in FIG. 9A, the scene 1 may be a situation prior to the generation of the scrap 72 from the workpiece 70, in which the upper die 61 is located upward away from the scrap 72.

In step S55, the arithmetic processor 16 may determine whether the antigravity force F′ is acting on the scrap 72. In step S55, if the arithmetic processor 16 determines that the antigravity force F′ is acting (step S55: Yes), the process may proceed to step S56, and the arithmetic processor 16 may determine whether the upper cutting blade 65 of the upper die 61 is in contact with the scrap 72. If the arithmetic processor 16 determines that the upper cutting blade 65 is not in contact, in other words, that the scrap 72 is not generated (step S56: No), the process may proceed to step S66. In step S66, the arithmetic processor 16 may increment the scene m, and the process may continue from step S55 again. For example, if, in step S66, the arithmetic processor 16 increments the scene m in the scene 1 illustrated in FIG. 9A, the scene 2 illustrated in FIG. 9B may be obtained.

If the arithmetic processor 16 determines in step S56 that the scrap 72 is in contact with the upper cutting blade 65 (step S56: Yes), in step S57, the arithmetic processor 16 may release the action of the antigravity force F′ on the scrap 72. In step S58, the arithmetic processor 16 may cause the random force F set by the random-force setter 24 to act on the scrap 72. In step S59, the arithmetic processor 16 may start the fall movement of the scrap 72. In step S60, the arithmetic processor 16 may start to count the fall time of the scrap 72. Steps S56 to S60 will be described below. First, the upper cutting blade 65 of the upper die 61 may come into contact with the scrap 72, and this may lead to a state in which the scrap 72 that is separated from the workpiece 70 is generated. At this timing, the antigravity force F′ for maintaining the scrap 72 in the rest state may be released. When the antigravity force F′ is released and the scrap 72 starts to fall, the random force F may be applied to the scrap 72 together with the force of gravity G that has already been applied to the scrap 72. With the force of gravity G and the random force F acting on the scrap 72, the scrap 72 may start to fall, and the counting of the fall time may start at this timing. FIG. 9C illustrates a scene in which the upper die 61 is in contact with the scrap 72, and the force of gravity G and the random force F are each indicated by an arrow. In step S66, the arithmetic processor 16 may increment the scene m, and the process may continue from step S55 again.

In step S55, if the arithmetic processor 16 determines that the antigravity force F′ is not acting on the scrap 72, in other words, that the scrap 72 is falling (step S55: No), the arithmetic processor 16 may determine in step S61 whether the fall velocity v of the scrap 72 is zero, in other words, whether the scrap 72 stops and is jammed. If the arithmetic processor 16 determines that the fall velocity v is not zero, in other words, that the scrap 72 is falling without being jammed (step S61: No), the process may proceed to step S62, and the arithmetic processor 16 may determine whether the fall time of the scrap 72 exceeds the set fall time Te.

If the arithmetic processor 16 determines in step S62 that the fall time of the scrap 72 does not exceed the fall time Te (step S62: No), the arithmetic processor 16 may set in step S63 the orientation of the scrap 72 in a present stage as a vector V2 using the unit normal vector V of the center of gravity of the scrap 72.

In step S64, the attitude-change-amount calculator 30 calculates the change amount U of the fall attitude based on Expression (6) described above, using the inner product between the vector V1 indicating the orientation of the scrap 72 in the previous stage and the vector V2 indicating the orientation of the scrap 72 in the present stage. In one embodiment, the calculating the change amount U of the fall attitude may serve as “calculating a change amount”. In the example embodiment, a change in the fall attitude may occur from the scene m=x(“x” is an integer of 2 or more) in which the falling of the scrap 72 starts. Accordingly, the attitude-change-amount calculator 30 may be set to calculate the change amount of the scrap 72 of from the scene x to the scene m in Expression (6). In step S65, the arithmetic processor 16 may set the orientation of the scrap 72 in the present stage as the vector V1. In step S66, the arithmetic processor 16 may increment the scene m, and the process may continue from step S55 again.

If the arithmetic processor 16 determines in step S61 that the fall velocity v is zero, in other words, that the scrap 72 stops and is jammed in the press apparatus 50 (step S61: Yes), the arithmetic processor 16 may set in step S68 the change amount U of the fall attitude of the scrap 72 to zero (change amount U=0). In step S69, the arithmetic processor 16 may increment the number of times en the scrap 72 has jammed (the number of times en the jam has occurred=en+1), and the process may proceed to step S70 illustrated in FIG. 11B. If the arithmetic processor 16 determines in step S61 that the fall velocity v is not zero (step S61: No), and determines in step S62 that the fall time of the scrap 72 exceeds the fall time Te (step S62: Yes), the process may proceed to step S70 illustrated in FIG. 11B.

In step S70, the attitude-change-amount calculator 30 may calculate the fall-attitude average change amount AveU of the scrap 72 using Expression (7) described above. In step S71, the degree-of-variation calculator 32 may calculate the variance σ^{b 2} that is the degree of variation of the change amount of the fall attitude of the scrap 72.

In step S72, the arithmetic processor 16 may determine whether the number of times n of the fall movement of the scrap 72 is greater than or equal to the set number of times N. If the arithmetic processor 16 determines that the number of times n is less than the set number of times N (step S72: No), the arithmetic processor 16 may increment the number of times n in step S73, and the process may continue from step S52 illustrated in FIG. 11A again.

If the arithmetic processor 16 determines in step S72 that the number of times n is greater than or equal to the set number of times N (step S72: Yes), the process may proceed to step S74, and the determiner 34 may determine whether the design quality of the press apparatus 50 is satisfactory or unsatisfactory based on a value of the calculated variance σ². The determiner 34 may determine that, if the value of the variance calculated in step S71 is less than or equal to the predetermined threshold, the design quality is satisfactory, and if the value of the variance exceeds the predetermined threshold, the design quality is low. The determiner 34 may further perform the determination based on the probability calculated by the probability calculator 28. In step S75, a result of the determination is displayed on, for example, the display of the display 18.

As described above, in the second example embodiment, a process after the scrap 72 starts to fall is similar to that of the first example embodiment. In the quality determination system 10 according to the example embodiment, the movement of the upper die 61 is added to simulation. This makes it possible, when the scrap 72 hits a wall surface of the support 67a or the scrap chute 56 and bounces upward upon falling, for example, to simulate a situation in which the scrap 72 hits the upper die 61 having moved downward and returns to the scrap chute 56. It is thus possible to take into account the movement of the upper die 61 that has actually been designed and to accurately simulate the behavior of the scrap 72 upon falling, and this improves accuracy of the simulation. As a result, it is possible to further improve the accuracy of predicting the failure in the falling of the scrap 72.

In addition, calculating the force to be acted on the scrap 72 when the upper die 61 moves downward and the scrap 72 is separated from the workpiece 70 can cause the amount of data for the calculation to be enormous. Accordingly, during a period until the upper die 61 separates the scrap 72, the force of gravity G and the force F′ that is in a direction opposite to the gravity direction that cancels the force of gravity G are caused to act on a part to be the scrap 72, which maintains the rest state of the scrap part. Thereafter, in the initial stage of the falling in which the upper die 61 comes into contact with the scrap 72 and the scrap 72 is separated, the force F′ in the opposite direction to the scrap 72 is released, and the force of gravity G and the random force F are caused to act on the scrap 72. This makes it possible to greatly suppress the amount of calculation of the force to be acted on the scrap 72 while simply reproducing the state of the scrap 72 until when the scrap 72 is separated by the upper die 61 and falls.

In the quality determination system 10 according to the example embodiments described above, the arithmetic processor 16 may determine the quality of the press apparatus 50. In some embodiments, the quality determination system 10 may include no determiner 34, and it is also possible for a user of the quality determination system 10 to perform the quality determination of the press apparatus 50 based on the change amount U of the fall attitude of the scrap 72 calculated by the attitude-change-amount calculator 30. For example, the user may use the simulation of the fall movement of the quality determination system 10 and repeatedly perform multiple times the fall movement of the scrap 72 to be fallen on the scrap chute 56 and to be discharged to the outside, and may determine, based on the change amount U of the fall attitude at each time, whether the change amount U of the fall attitude of the scrap 72 is approximately the same every time. If the user determines that the change amount U of the fall attitude of the scrap 72 when the scrap 72 is discharged to the outside is approximately the same every time, the user may determine that the trouble that the scrap 72 remains inside the press apparatus 50 is prevented from occurring easily. In contrast, if the user determines that the change amount U of the fall attitude of the scrap 72 when the scrap 72 is discharged to the outside greatly differs every time, the user may determine that the fall attitude is unstable and that it is highly possible that the trouble that the scrap 72 remains inside the press apparatus 50 occurs.

Although some example embodiments of the disclosure have been described in the foregoing by way of example with reference to the accompanying drawings, the disclosure is by no means limited to the embodiments described above. It should be appreciated that modifications and alterations may be made by persons skilled in the art without departing from the scope as defined by the appended claims. The disclosure is intended to include such modifications and alterations in so far as they fall within the scope of the appended claims or the equivalents thereof.

According to at least one embodiment of the disclosure, it is possible to improve accuracy of predicting a failure in falling of a scrap in determining a quality of a press apparatus, with use of a simulation of the falling of the scrap in the press apparatus.

1. A press apparatus quality determination method to be performed with use of a simulation of falling of a scrap, the simulation including creating a three-dimensional model of a press die of a press apparatus, the scrap generated from a workpiece that is processed by the press die, and a scrap chute that guides the scrap to an outside of the press apparatus, and simulating a movement of the scrap to be fallen on the scrap chute and to be discharged to the outside, the press apparatus quality determination method comprising:
causing a force of gravity and a force that comprises a random magnitude within a range of a predetermined magnitude to act on the scrap generated from the workpiece in an initial stage of falling of the scrap on the scrap chute; and
calculating, based on the causing the force of gravity and the force having the random magnitude to act on the scrap, a change amount of a fall attitude of the scrap from a start of the falling to an end of the falling.

2. The press apparatus quality determination method according to claim 1, further comprising:
calculating, by repeating the calculating the change amount a predetermined number of times, a degree of variation of the change amount of the fall attitude in the predetermined number of times; and
determining that a design quality of the press apparatus is satisfactory when the degree of variation is less than or equal to a predetermined threshold.

3. The press apparatus quality determination method according to claim 1, wherein the calculating the change amount comprises using an inner product of a vector having a predetermined magnitude that extends in a predetermined direction from a predetermined point of the scrap to determine the change amount of the fall attitude of the scrap.

4. The press apparatus quality determination method according to claim 2, wherein the calculating the change amount comprises using an inner product of a vector having a predetermined magnitude that extends in a predetermined direction from a predetermined point of the scrap to determine the change amount of the fall attitude of the scrap.

5. The press apparatus quality determination method according to claim 1, wherein
the simulation comprises data that the press die comprises a lower die and an upper die, and movement data that a downward movement of the upper die with respect to the lower die generates the scrap,
the press apparatus quality determination method further comprises, prior to the calculating the change amount, maintaining a rest state of the scrap by causing the force of gravity and a force that is in a direction opposite to a gravity direction and comprises a magnitude that is equal to a magnitude of the force of gravity to act on the scrap, during a period from when the upper die moves downward to when the scrap is generated, and
the calculating the change amount comprises taking into account a movement of the upper die.

6. A press apparatus quality determination system comprising
an arithmetic processor configured to create a three-dimensional model of a press die of a press apparatus, a scrap generated from a workpiece that is processed by the press die, and a scrap chute that guides the scrap to an outside of the press apparatus, and simulate a movement of the scrap to be fallen on the scrap chute and to be discharged to the outside, wherein
the arithmetic processor comprises:
a force applier configured to cause a force of gravity and a force that comprises a random magnitude within a range of a predetermined magnitude to act on the scrap generated from the workpiece in an initial stage of falling of the scrap on the scrap chute; and
an attitude-change-amount calculator configured to calculate a change amount of a fall attitude of the scrap from a start of the falling to an end of the falling.

7. The press apparatus quality determination system according to claim 6, wherein
the arithmetic processor is configured to store data that the press die comprises a lower die and an upper die, and movement data that a downward movement of the upper die with respect to the lower die generates the scrap,
the force applier is configured to cause the force of gravity and a force that is in a direction opposite to a gravity direction and comprises a magnitude that is equal to a magnitude of the force of gravity to act on the scrap, during a period from when the upper die moves downward to when the scrap is generated, and
the arithmetic processor is configured to calculate the change amount of the fall attitude by taking into account a movement of the upper die.

8. A non-transitory computer readable recording medium containing a press apparatus quality determination program, the press apparatus quality determination program causing, when executed by a computer, the computer to perform a method to be performed with use of a simulation of falling of a scrap, the simulation including creating a three-dimensional model of a press die of a press apparatus, the scrap generated from a workpiece that is processed by the press die, and a scrap chute that guides the scrap to an outside of the press apparatus, and simulating a movement of the scrap to be fallen on the scrap chute and to be discharged to the outside, the method comprising:
causing a force of gravity and a force that comprises a random magnitude within a range of a predetermined magnitude to act on the scrap generated from the workpiece in an initial stage of falling of the scrap on the scrap chute; and
calculating, based on the causing the force of gravity and the force having the random magnitude to act on the scrap, a change amount of a fall attitude of the scrap from a start of the falling to an end of the falling.

9. The non-transitory recording medium according to claim 8, wherein
the simulation comprises data that the press die comprises a lower die and an upper die, and movement data that a downward movement of the upper die with respect to the lower die generates the scrap,
the method further comprises, prior to the calculating the change amount, maintaining a rest state of the scrap by causing the force of gravity and a force that is in a direction opposite to a gravity direction and comprises a magnitude that is equal to a magnitude of the force of gravity to act on the scrap, during a period from when the upper die moves downward to when the scrap is generated, and
the calculating the change amount comprises taking into account a movement of the upper die.
